(19) United States
(12) Patent Application Publication
(10) Pub. No.: US 2019/0081619 A1
(43) Pub. Date: Mar. 14, 2019

(54) DUTY CYCLE CORRECTION CIRCUIT AND CLOCK CORRECTION CIRCUIT INCLUDING THE SAME

(71) Applicants: SK hynix Inc., Gyeonggi-do (KR); Seoul National University R&DB Foundation, Seoul (KR)

(72) Inventors: Suhwan KIM, Seoul (KR); Joo-Hyung CHAE, Seoul (KR); Deog-Kyoon JEONG, Seoul (KR)

(21) Appl. No.: 15/965,505

(22) Filed: Apr. 27, 2018

(30) Foreign Application Priority Data
Sep. 12, 2017 (KR) 10-2017-0116486

(51) Int. Cl. H03K 5/156

(52) U.S. Cl. CPC H03K 5/1565

(57) ABSTRACT

A duty cycle correction circuit includes a first inverter suitable for driving a second clock in response to a first clock; a second inverter suitable for driving the first clock in response to the second clock; and a duty cycle detector suitable for detecting a duty cycle of the first clock or the second clock, wherein driving forces of one or more inverters among the first inverter and the second inverter are controlled based on a duty detection result of the duty cycle detector.

### CROSS-REFERENCE TO RELATED APPLICATIONS

The present application claims priority of Korean Patent Application No. 10-2017-0116486, filed on Sep. 12, 2017, which is incorporated herein by reference in its entirety.

### BACKGROUND

### 1. Field

Exemplary embodiments of the present invention relate to a duty cycle correction circuit and a clock correction circuit including the duty cycle correction circuit.

### 2. Description of the Related Art

As the data transfer rate of diverse integrated circuits, such as a memory, increases, it becomes burdensome to use a clock of a high frequency for transferring data between integrated circuits in the inside of an integrated circuit, for example, a semiconductor memory device. To solve this problem, multi-phase clocks of lower frequencies than the clock used for transferring data between integrated circuits may be used in the inside of an integrated circuit chip, for example a semiconductor memory device.

FIG. 1 illustrates an example of multi-phase clocks.

Referring to FIG. 1, four clocks ICK, QCK, IBCK and QBCK may have a phase difference of approximately 90 degrees (°) from each other.

Referring to FIG. 1, the four clocks ICK, QCK, IBCK and QBCK may have a phase difference of approximately 90° from each other. Rising edges of the clocks ICK and QCK may have a phase difference of approximately 90° from each other, and the rising edges of the clocks QCK and IBCK may have a phase difference of approximately 90° from each other. Also, the rising edges of the clocks IBCK and QBCK may have a phase difference of approximately 90° from each other. Also, all the four clocks ICK, QCK, IBCK and QBCK may have a duty cycle ratio of approximately 50%. In short, all the four clocks ICK, QCK, IBCK and QBCK may have the same high pulse width and the same low pulse width.

FIG. 1 shows a case where the multi-phase clocks ICK, QCK, IBCK and QBCK have the most ideal phase difference and duty cycle ratio. However, when the multi-phase clocks ICK, QCK, IBCK and QBCK are used in the inside of an actual integrated circuit, for example, a semiconductor memory device, the phase difference between the clocks ICK, QCK, IBCK and QBCK is not maintained at approximately 90 θ due to various noises in the inside of the integrated circuit, and the duty cycle ratio of the clocks ICK, QCK, IBCK and QBCK is not maintained at approximately 50%.

Embodiments of the present invention are directed to a technology capable of accurately correcting a duty cycle ratio and phase difference between multi-phase clocks.

In accordance with an embodiment of the present invention, a duty cycle correction circuit includes: a first inverter suitable for driving a second clock in response to a first clock; a second inverter suitable for driving the first clock in response to the second clock; and a duty cycle detector suitable for detecting a duty of the first clock and the second clock, and driving forces of one or more inverters among the first inverter and the second inverter are controlled based on a duty detection result of the duty cycle detector.

When the duty detection result shows that a high pulse width of the first clock is longer than a high pulse width of the second clock, a driving force of the second inverter may be increased, and when the duty detection result shows that the high pulse width of the second clock is longer than the high pulse width of the first clock, a driving force of the first inverter may be increased.

When the duty detection result shows that a high pulse width of the first clock is longer than a high pulse width of the second clock, a driving force of the first inverter may be decreased, and when the duty detection result shows that the high pulse width of the second clock is longer than the high pulse width of the first clock, a driving force of the second inverter may be decreased.

The duty cycle detector may include: a first low pass filter suitable for filtering the first clock; a second low pass filter suitable for filtering the second clock; and a comparator suitable for generating the duty detection result by comparing a filtering value of the first low pass filter with a filtering value of the second low pass filter.

The duty cycle correction circuit may further include: a driving force controlling circuit suitable for controlling driving forces of the first inverter and the second inverter in response to the duty detection result of the duty cycle detector.

The duty cycle correction circuit may further include: a first driver suitable for transferring the first clock to an input terminal of the first inverter; a second driver suitable for transferring the second clock to an input terminal of the second inverter; a third driver suitable for transferring the first clock over an output terminal of the second inverter to the duty cycle detector; and a fourth driver suitable for transferring the second clock over an output terminal of the first inverter to the duty cycle detector.

In accordance with another embodiment of the present invention, a clock correction circuit includes: a first duty cycle correction circuit suitable for correcting a duty of a first clock and a duty of a second clock; a second duty cycle correction circuit suitable for correcting a duty of a third clock and a duty of a fourth clock; a phase skew detector suitable for detecting a phase difference between the first clock and the third clock; and a delay circuit suitable for delaying the first clock and the second clock by a first delay value and delaying the third clock and the fourth clock by a second delay value, wherein one or more delay values between the first delay value and the second delay value are controlled based on a detection result of the phase skew detector.

A target duty cycle ratio of the first to fourth clocks is approximately 50%, a target phase difference between the first clock and the third clock is approximately 900, a target phase difference between the third clock and the second clock is approximately 90°, and a target phase difference between the second clock and the fourth clock is approximately 90°.

When the detection result of the phase skew detector shows that a phase difference between the first clock and the third clock is greater than approximately 900, the first delay value is controlled to be increased, and when the detection result of the phase skew detector shows that a phase difference between the first clock and the third clock is smaller than approximately 90°, the second delay value is controlled to be increased.

When the detection result of the phase skew detector shows that a phase difference between the first clock and the third clock is greater than approximately 90°, the second delay value is controlled to be decreased, and when the detection result of the phase skew detector shows that a phase difference between the first clock and the third clock is smaller than approximately 90°, the first delay value is controlled to be decreased.

The phase skew detector may include: a first pulse generator suitable for generating a first pulse signal which is enabled from a rising edge of the first clock and a rising edge of the third clock; a second pulse generator suitable for generating a second pulse signal which is enabled from a rising edge of the third clock and a falling edge of the first clock; and a pulse width comparison circuit suitable for generating the detection result of the phase skew detector by comparing a pulse width of the first pulse signal with a pulse width of the second pulse signal.

The pulse width comparison circuit may include: a first capacitor that is coupled between a first node and a ground terminal; a second capacitor that is coupled between a second node and the ground terminal; a first current source suitable for supplying a current to the first node in response to the first pulse signal; a second current source suitable for supplying a current to the second node in response to the second pulse signal; and a comparator suitable for generating the detection result of the phase skew detector by comparing a voltage level of the first node with a voltage level of the second node.

The clock correction circuit of claim 8 may further include: a delay value controlling circuit suitable for controlling the first delay value and the second delay value in response to the detection result of the phase skew detector.

The first duty cycle correction circuit may include: a first inverter suitable for driving the second clock in response to the first clock; a second inverter suitable for driving the first clock in response to the second clock; and a first duty cycle detector suitable for detecting a duty of the first clock and a duty of the second clock, and driving forces of one or more inverters between the first inverter and the second inverter are controlled based on the detection result of the first duty cycle detector.

The second duty cycle correction circuit includes: a third inverter suitable for driving the fourth clock in response to the third clock; a fourth inverter suitable for driving the third clock in response to the fourth clock; and a second duty cycle detector suitable for detecting a duty of the third clock and a duty of the fourth clock, and driving forces of one or more inverters between the third inverter and the fourth inverter are controlled based on the duty detection result of the second duty cycle detector.

When the duty detection result of the first duty cycle detector shows that a high pulse width of the first clock is longer than a high pulse width of the second clock, a driving force of the second inverter may be increased, and when the duty detection result of the first duty cycle detector shows that a high pulse width of the second clock is longer than a high pulse width of the first clock, a driving force of the first inverter may be increased, and when the duty detection result of the second duty cycle detector shows that a high pulse width of the third clock is longer than a high pulse width of the fourth clock, a driving force of the fourth inverter may be increased, and when the duty detection result of the second duty cycle detector shows that a high pulse width of the fourth clock is longer than a high pulse width of the third clock, a driving force of the third inverter may be increased.

When the duty detection result of the first duty cycle detector shows that a high pulse width of the first clock is longer than a high pulse width of the second clock, a driving force of the first inverter may be decreased, and when the duty detection result of the first duty cycle detector shows that a high pulse width of the second clock is longer than a high pulse width of the first clock, a driving force of the second inverter may be decreased, and when the duty detection result of the second duty cycle detector shows that a high pulse width of the third clock is longer than a high pulse width of the fourth clock, a driving force of the third inverter may be decreased, and when the duty detection result of the second duty cycle detector shows that a high pulse width of the fourth clock is longer than a high pulse width of the third clock, a driving force of the fourth inverter may be decreased.

The delay circuit may include: a first variable delay line suitable for delaying the first clock by the first delay value that is controlled based on the detection result of the phase skew detector; a second variable delay line suitable for delaying the second clock by the first delay value; a third variable delay line suitable for delaying the third clock by the second delay value that is controlled based on the detection result of the phase skew detector; and a fourth variable delay line suitable for delaying the fourth clock by the second delay value.

In accordance with another embodiment of the present invention, a clock correction circuit for use in a semiconductor memory device may include: a first inverter suitable for driving a second clock in response to a first clock; a second inverter suitable for driving the first clock in response to the second clock; a duty cycle detector suitable for detecting a duty cycle of the first clock or the second clock; and a driving force controlling circuit suitable for controlling driving forces of one or more inverters among the first inverter and the second inverter based on a duty detection result of the duty cycle detector to correct the duty cycle of the first clock and the duty cycle of the second clock.

The clock correction circuit may further include: a third inverter suitable for driving a fourth clock in response to a third clock; a fourth inverter suitable for driving the third clock in response to the fourth clock; a second duty cycle detector suitable for detecting a duty cycle of the third clock or the fourth clock; and a second driving force controlling circuit suitable for controlling driving forces of one or more inverters among the third inverter and the fourth inverter based on a duty detection result of the duty cycle detector to correct the duty cycle of the third and the duty cycle of the fourth clock.

The clock correction circuit may further include: a phase skew detector suitable for detecting a phase difference between the first clock and the third clock; and a delay circuit suitable for delaying the first clock and the second clock by a first delay value and delaying the third clock and the fourth clock by a second delay value, wherein one or more delay values of the first delay value and the second delay value are controlled based on a detection result of the phase skew detector.

### BRIEF DESCRIPTION OF THE DRAWINGS

FIG. 1 a timing diagram illustrating an example of multi-phase clocks.

FIG. 2 is a schematic diagram illustrating inverters coupled in a cross-coupled form in accordance with an embodiment of the present invention.

FIG. 3A is a timing diagram illustrating clocks ICK and IBCK shown in FIG. 2.

FIG. 3B is a timing diagram illustrating clocks ICK_1 and IBCK_1 shown in FIG. 2.

FIG. 4 is a diagram illustrating a duty cycle correction circuit in accordance with an embodiment of the present invention.

FIG. 5 is a schematic diagram illustrating a first inverter and a second inverter shown in FIG. 4.

FIG. 6 is a schematic diagram illustrating a duty cycle detector shown in FIG. 4.

FIG. 7A is a timing diagram illustrating the clocks ICK and IBCK shown in FIG. 5.

FIG. 7B is a timing diagram illustrating the clocks ICK_1 and IBCK_1 shown in FIG. 5.

FIG. 8 is a schematic diagram illustrating a clock correction circuit in accordance with an embodiment of the present invention.

FIG. 9 is a schematic diagram illustrating a phase skew detector shown in FIG. 8.

FIG. 10 is a timing diagram illustrating clocks ICK_2 and QCK_2 and pulse signals C and D shown in FIG. 9.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

FIG. 2 is a schematic diagram illustrating inverters that are coupled in a cross-coupled form that is used to prevent an enable section of a clock ICK and an enable section of a clock IBCK from overlapping with each other in accordance with an embodiment of the present invention.

Referring to FIG. 2, drivers 211 and 212 may be used to transfer the clock ICK in the inside of an integrated circuit, and drivers 221 and 222 may be used to transfer the clock IBCK in the inside of the integrated circuit. Each of the drivers 211, 212, 221 and 222 may include two or more inverters. A clock ICK_1 and a clock ICK_2 may represent the clock ICK that is transferred by the drivers 211 and 212, respectively, and a clock IBCK_1 and a clock IBCK_2 may represent the clock IBCK that is transferred by the drivers 221 and 222, respectively.

The inverters I21 and I22 that are coupled in a cross-coupled form may be used to prevent the enable sections of the clock ICK_1 and the clock IBCK_1 from overlapping with each other. The inverter I21 may drive the clock IBCK_1 in response to the clock ICK_1, and the inverter I22 may drive the clock ICK_1 in response to the clock IBCK_1.

The inverters I21 and I22 may be designed to have stronger driving forces than the driving forces of the inverters in the inside of the drivers 211, 212, 221 and 222. That is, the driving forces of the inverters I21 and I22 may be more than twice as strong as the driving forces of the drivers 211, 212, 221 and 222. In this case, the enable sections of the clocks ICK_1 and IBCK_1 are prevented from overlapping with each other because the inverters I21 and I22 make the clock ICK_1 and the clock IBCK_1 to have an inverted phase.

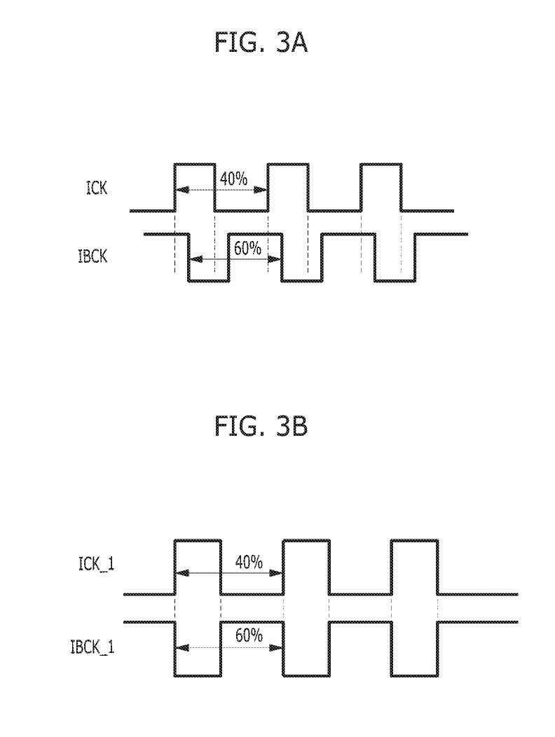

FIG. 3A illustrates the clocks ICK and IBCK. Referring to FIG. 3A, it may be seen that the clocks ICK and IBCK overlap with each other in the enable section, which is a high pulse section. FIG. 3B illustrates clocks ICK_1 and IBCK_1. It may be seen from FIG. 3B that the inverters I21 and I22 prevent the clocks ICK_1 and IBCK_1 from overlapping with each other. However, a high pulse width of the clock ICK_1 may be approximately 40% of one cycle, that is, the duty cycle ratio may be approximately 40%, and a high pulse width of the clock IBCK_1 may be approximately 60% of one cycle, that is, the duty cycle ratio may be approximately 60%. That is, it may be possible to prevent the enable sections of the clocks ICK_1 and ICKB_1 from overlapping with each other due to the use of the inverters I21 and I22 that are coupled in a cross-coupled form, but the duty cycle ratio of the clocks ICK_1 and ICKB_1 may be corrected into approximately 50%. Depending on the cases, the duty cycle ratio of the clocks ICK_1 and ICKB_1 may become worse than that of the clocks ICK and ICKB due to the inverters I21 and I22.

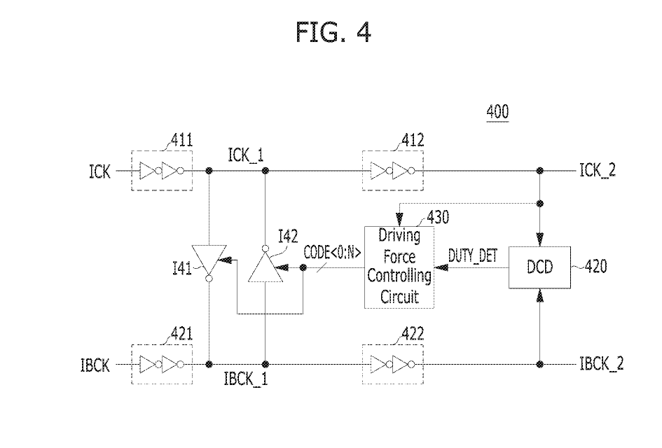

FIG. 4 is a schematic diagram illustrating a duty cycle correction circuit 400 in accordance with an embodiment of the present invention.

Referring to FIG. 4, the duty cycle correction (DCC) circuit 400 may include a first inverter I41, a second inverter I42, a duty cycle detector 420, a driving force controlling circuit 430, and drivers 411, 412, 421 and 422.

The drivers 411 and 412 may be used to transfer a clock ICK, and drivers 421 and 422 may be used to transfer the clock IBCK. Each of the drivers 411, 412, 421 and 422 may include two or more inverters. A clock ICK_1 and a clock ICK_2 may represent the clock ICK that is transferred by the drivers 411 and 412, respectively, and a clock IBCK_1 and a clock IBCK_1 may represent the clock IBCK that is transferred by the drivers 421 and 422, respectively.

The inverters I41 and I42 that are coupled in a cross-coupled form may be used to prevent the enable sections of the clock ICK_1 and the clock IBCK_1 from overlapping with each other, and to correct the duty cycle of the clocks ICK_1 and IBCK_1 into approximately 50%. The inverter I41 may drive the clock IBCK_1 in response to the clock ICK_1, and the inverter 142 may drive the clock ICK_1 in response to the clock IBCK_1. Since the driving forces of the first inverter I41 and the second inverter I42 are controlled based on the duty detection result DUTY_DET of the duty cycle detector 420, not only the enable sections of the clocks ICK_1 and IBCK_1 are controlled not to overlap with each other due to the first inverter I41 and the second inverter I42, but also the duty cycle ratio of the clocks ICK_1 and IBCK_1 may be controlled to approximately 50%.

The duty cycle detector 420 may sense the duty cycle ratio of the clocks ICK_2 and IBCK_2. Herein, the duty cycle ratio of the clocks ICK_2 and IBCK_2 and the duty cycle ratio of the clocks ICK_1 and IBCK_1 may be the same. The duty detection result DUTY_DET of the duty cycle detector 420 may represent which one between the high pulse width of the clock ICK_2 and the high pulse width of the clock IBCK_2 is longer. For example, when the high pulse width of the clock ICK_2 is longer than the high pulse width of the clock IBCK_2, the duty detection result DUTY_DET may be in a logic high level. When the high pulse width of the clock IBCK_2 is longer than the high pulse width of the clock ICK_2, the duty detection result DUTY_DET may be in a logic low level.

The driving force controlling circuit 430 may control the driving forces of the first inverter I41 and the second inverter I42 in response to the duty detection result DUTY_DET. The driving force controlling circuit 430 may increase the driving force of the second inverter I42 when the high pulse width of the clock ICK_2 is longer than the high pulse width of the clock IBCK_2, that is, when the duty detection result DUTY_DET is in a logic high level. Also, the driving force controlling circuit 430 may increase the driving force of the first inverter I41 when the high pulse width of the clock IBCK_2 is longer than the high pulse width of the clock ICK_2, that is, when the duty detection result DUTY_DET is in a logic low level. Since it is important to control the relative driving forces of the first inverter I41 and the second inverter I42 to control the duty cycles, the driving force of the second inverter I42 may be decreased instead of increasing the driving force of the first inverter I41, and the driving force of the second inverter I42 may be decreased along with increasing the driving force of the first inverter I41. Conversely, the driving force of the first inverter I41 may be decreased instead of increasing the driving force of the second inverter I42, and the driving force of the first inverter I41 may be decreased along with increasing the driving force of the second inverter I42. The driving force controlling circuit 430 may be a counter that increases or decreases a code in response to the duty detection result whenever the clock ICK_2 is enabled. For example, when the clock ICK_2 is enabled and the duty detection result DUTY_DET is in a logic high level, the driving force controlling circuit 430 may increase the code CODE<0:N>, where N is an integer that is equal to or greater than ‘1’, and when the clock ICK_2 is enabled and the duty detection result DUTY_DET is in a logic low level, the driving force controlling circuit 430 may decrease the code CODE<0:N>.

Although FIG. 4 shows an example where the driving forces of the first inverter I41 and the second inverter I42 are controlled based on the code CODE<0:N> generated by the driving force controlling circuit 430, it may be possible to perform a duty cycle correction operation of the clocks ICK_1 and IBCK_1 by controlling only the driving force of one inverter between the first inverter I41 and the second inverter I42 based on the code CODE<0:N>.

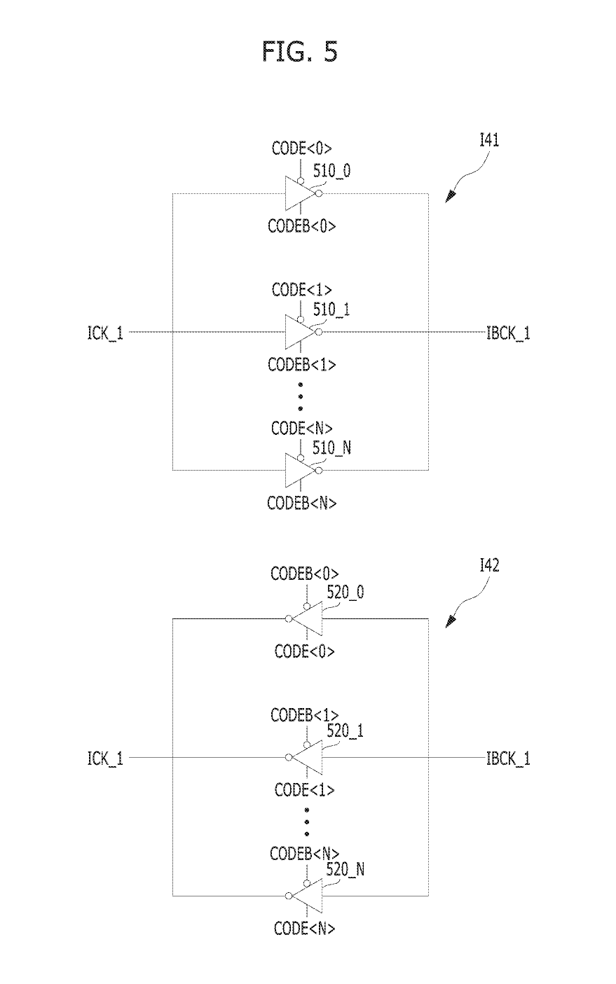

FIG. 5 is a schematic diagram illustrating the first inverter I41 and the second inverter I42 shown in FIG. 4.

Referring to FIG. 5, the first inverter I41 may include a plurality of tri-state inverters 510_0 to 510_N. The tri-state inverters 510_0 to 510_N may be enabled/disabled in response to the code CODE<0:N>. In FIG. 5, a code CODEB<0:N> may represent an inverted code CODE<0:N>. As the value of the code CODE<0:N> is decreased, the number of inverters that are enabled among the tri-state inverters 510_0 to 510_N may be increased. Therefore, as the value of the code CODE<0:N> is decreased, the driving force of the first inverter I41 may be increased.

The second inverter I42 may include a plurality of tri-state inverters 520_0 to 520_N. The tri-state inverters 520_0 to 520_N may be enabled/disabled in response to the code CODE<0:N>. As the value of the code CODE<0:N> is increased, the number of inverters that are enabled among the tri-state inverters 520_0 to 520_N may be increased. Therefore, as the value of the code CODE<0:N> is increased, the driving force of the second inverter I42 may be increased.

In short, as the value of the code CODE<0:N> is increased, the driving force of the second inverter I42 may be relatively stronger than the driving force of the first inverter I41, and as the value of the code CODE<0:N> is decreased, the driving force of the first inverter I41 may be relatively stronger than the driving force of the second inverter I42.

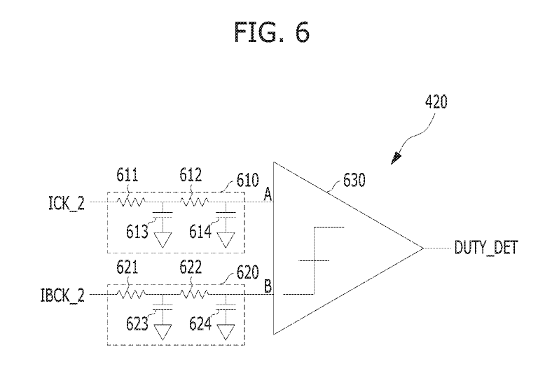

FIG. 6 is a schematic diagram illustrating a duty cycle detector 420 shown in FIG. 4.

Referring to FIG. 6, the duty cycle detector 420 may include a first Low pass filter 610, a second Low pass filter 620, and a comparator 630.

The first Low pass filter 610 may filter the clock ICK_2 and transfer the filtered clock to the comparator 630. As a high pulse width of the clock ICK_2 is longer than a Low pulse width of the first Low pass filter 610, the level of a voltage A applied to the comparator 630 through the first Low pass filter 610 may be increased. As a high pulse width of the clock ICK_2 is longer than a Low pulse width, the level of the voltage A applied to the comparator 630 through the first Low pass filter 610 may be decreased. The first Low pass filter 610 may include resistors 611 and 612 and capacitors 613 and 614.

The second Low pass filter 620 may filter the clock IBCK_2 and transfer the filtered clock to the comparator 630. As a high pulse width of the clock IBCK_2 is longer than a Low pulse width of the second low pass filter 620, the level of a voltage B applied to the comparator 630 through the second Low pass filter 620 may be increased. As a high pulse width of the clock IBCK_2 is longer than a Low pulse width, the level of the voltage B applied to the comparator 630 through the second Low pass filter 620 may be decreased. The second Low pass filter 620 may include resistors 621 and 622 and capacitors 623 and 624.

The comparator 630 may compare the level of the voltage A with the level of the voltage B, and output the duty detection result DUTY_DET. If the level of the voltage A is higher than the level of the voltage B, it may mean that the high pulse width of the clock ICK_2 is longer than high pulse width of the clock IBCK_2. In this case, the comparator 630 may output the duty detection result DUTY_DET in a logic high level. If the level of the voltage B is higher than the level of the voltage A, it may mean that the high pulse width of the clock IBCK_2 is longer than high pulse width of the clock ICK_2. In this case, the comparator 630 may output the duty detection result DUTY_DET in a logic low level.

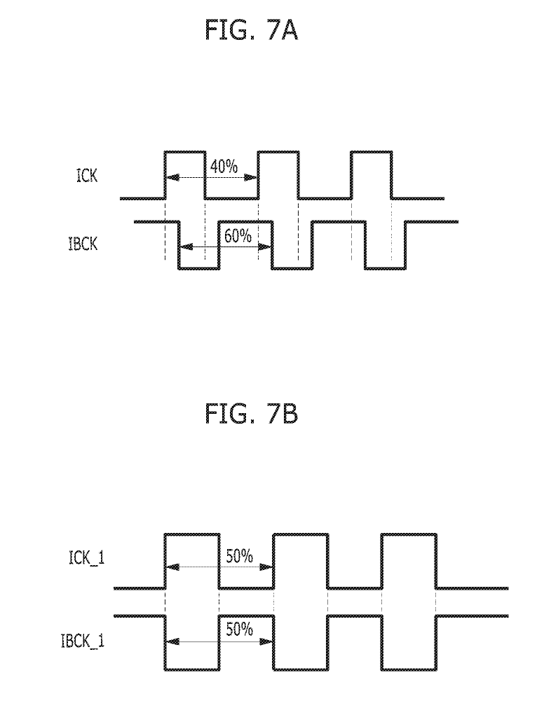

FIG. 7A illustrates the clocks ICK and IBCK shown in FIG. 5. Referring to FIG. 7A, it may be seen that the enable sections of the clocks ICK and IBCK overlap with each other and the duty cycle ratio of the clocks ICK and IBCK is not approximately 50%. FIG. 7B illustrates the clocks ICK_1 and IBCK_1 shown in FIG. 5. Due to the operations of the inverters I41 and I42 whose driving forces are controlled based on the duty detection result DUTY_DET, the enable sections of the clocks ICK and IBCK may not overlap with each other and the duty cycle ratio of the clocks ICK_and IBCK_1 may be approximately 50%.

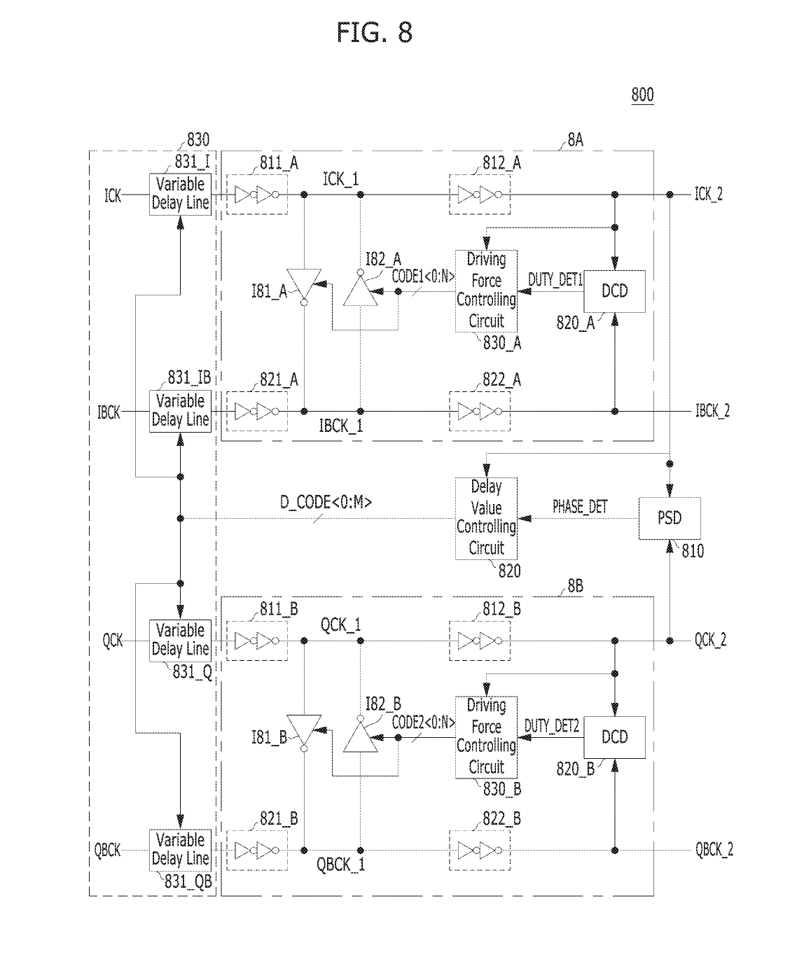

FIG. 8 is a schematic diagram illustrating a clock correction circuit 800 in accordance with an embodiment of the present invention. Herein, the clock correction circuit 800 may be a circuit capable of correcting the phase difference and duty cycle ratio of the multi-phase clocks ICK, QCK, IBCK and QBCK.

Referring to FIG. 8, the clock correction circuit 800 may include a first duty cycle correction circuit 8A, a second duty cycle correction circuit 8B, a phase skew detector (PSD) 810, a delay value controlling circuit 820, and a delay circuit 830.

The first duty cycle correction circuit 8A may control the enable sections of the clock ICK_1 and the clock IBCK_1 not to overlap with each other and correct the duty cycle ratio of the clock ICK_1 and the clock IBCK_1 to approximately 50%. The first duty cycle correction circuit 8A may include inverters I81_A and I82_A, a duty cycle detector 820_A, a driving force controlling circuit 830_A, and drivers 811_A, 812_A, 821_A and 822_A. The first duty cycle correction circuit 8A may include the same constituent elements as those of the duty cycle correction circuit 400 shown in FIG. 4 and operate in the same way.

The second duty cycle correction circuit 8B may control the enable sections of the clock QCK_1 and the clock QBCK_1 not to overlap with each other and correct the duty cycle ratio of the clock QCK_1 and the clock QBCK_1 to approximately 50%. The second duty cycle correction circuit 8B may include inverters I81_B and I82_B, a duty cycle detector 820_B, a driving force controlling circuit 830_B, and drivers 811_B, 812_B, 821_B and 822_B. The second duty cycle correction circuit 8B may include the same constituent elements as those of the duty cycle correction circuit 400 shown in FIG. 4 and operate in the same way.

The phase skew detector 810 may be able to detect a phase difference between the clock ICK_2 and the clock QCK_2. The phase skew detector 810 may generate a phase detection result PHASE_DET which represents whether the phase difference between the clock ICK_2 and the clock QCK_2 is greater than approximately 90° or smaller than approximately 90°. When the phase difference between the clock ICK_2 and the clock QCK_2 is greater than approximately 90°, the phase detection result PHASE_DET may have a logic low level. When the phase difference between the clock ICK_2 and the clock QCK_2 is smaller than approximately 900, the phase detection result PHASE_DET may have a logic high level. Herein, since the phase difference between the clock ICK_2 and the clock IBCK_2 and the phase difference between the clock ICK_1 and the clock IBCK_1 are the same, the output from the phase skew detector 810 may be considered as the phase difference between the clock ICK_1 and the clock IBCK_1.

The delay circuit 830 may delay the clocks ICK and IBCK by a first delay unit, and delay the clocks QCK and QBCK by a second delay unit. The first delay unit and the second delay unit may be controlled based on the phase detection result PHASE_DET. The delay circuit 830 may include a first variable delay line 831_1 for delaying the clock ICK by the first delay value that is controlled based on the phase detection result PHASE_DET, a second variable delay line 831_IB for delaying the clock IBCK by the first delay value that is controlled based on the phase detection result PHASE_DET, a third variable delay line 831_Q for delaying the clock QCK by the second delay value that is controlled based on the phase detection result PHASE_DET, and a fourth variable delay line 831_QB for delaying the clock QBCK by the second delay value that is controlled based on the phase detection result PHASE_DET. The first variable delay line 831_I and the second variable delay line 831_IB may have the same first delay value, and the first delay value may have a smaller value as the value of a delay code D_CODE<0:M> is increased, where M is an integer that is equal to or greater than 1. The third variable delay line 831_Q and the fourth variable delay line 831_QB may have the same second delay value, and the second delay value may have a greater value as the value of the delay code D_CODE<0:M> is increased.

The delay value controlling circuit 820 may control the delay value of the delay circuit 830 in response to the phase detection result PHASE_DET. The delay value controlling circuit 820 may increase the first delay value and decrease the second delay value so as to reduce the phase difference between the clock ICK_2 and the clock QCK_2, when the phase detection result PHASE_DET represents that the phase difference between the clock ICK_2 and the clock QCK_2 is greater than approximately 90°, that is, when the phase detection result PHASE_DET is in a logic low level. Also, when the phase detection result PHASE_DET represents that the phase difference between the clock ICK_2 and the clock QCK_2 is smaller than approximately 900, that is, when the phase detection result PHASE_DET is in a logic high level, the delay value controlling circuit 820 may decrease the first delay value and increase the second delay value so as to reduce the phase difference between the clock ICK_2 and the clock QCK_2. Since it is important to control the relative delay value of the first delay value and the second delay value to control the phase difference between the clock ICK_2 and the clock QCK_2, the delay value controlling circuit 820 may control one delay value of the first delay value and the second delay value. That is, the delay value controlling circuit 820 may control the delay value in a manner that the delay value is not decreased but increased, or i is not increased but decreased. The delay value controlling circuit 820 may be a counter that increases or decreases the delay code D_CODE<0:M> in response to the phase detection result PHASE_DET whenever the clock ICK_2 is enabled. For example, the delay value controlling circuit 820 may increase the delay code D_CODE<0:M> when the clock ICK_2 is enabled and the phase detection result PHASE_DET is in a logic high level. When the clock ICK_2 is enabled and the phase detection result PHASE_DET is in a logic low level, the delay value controlling circuit 820 may decrease the delay code D_CODE<0:M>.

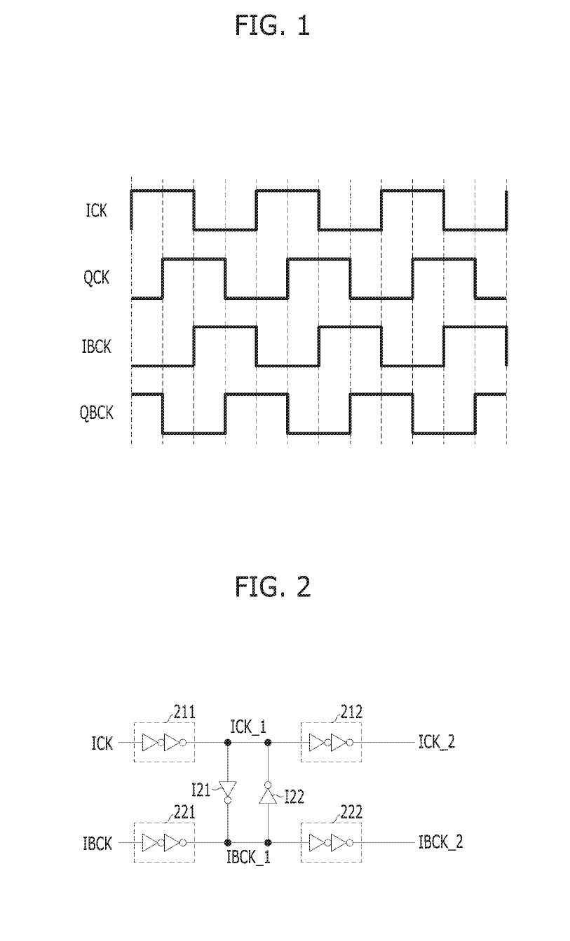

In the clock correction circuit 800, the first duty cycle correction circuit 8A may control the enable sections of the clocks ICK_2 and IBCK_2 not to overlap with each other. In other words, the first duty cycle correction circuit 8A may control the phase difference between the clocks ICK_2 and IBCK_2 to be approximately 180° and control the duty cycle ratio of the clocks ICK_2 and IBCK_2 to be approximately 50%. Also, the second duty cycle correction circuit 8B may control the enable sections of the clocks QCK_2 and QBCK_2 not to overlap with each other. In other words, the second duty cycle correction circuit 8B may control the phase difference between the clocks QCK_2 and QBCK_2 to be approximately 1800 and control the duty cycle ratio of the clocks QCK_2 and QBCK_2 to be approximately 50%. The phase skew detector 810, the delay value controlling circuit 820, and the delay circuit 830 may control the phase difference between the clocks ICK_2 and QCK_2 to be approximately 900. After all, the clocks ICK_2, QCK_2, IBCK_2 and QBCK_2 may have an ideal phase difference and an ideal duty cycle ratio just as shown in FIG. 1 through the operation of the clock correction circuit 800.

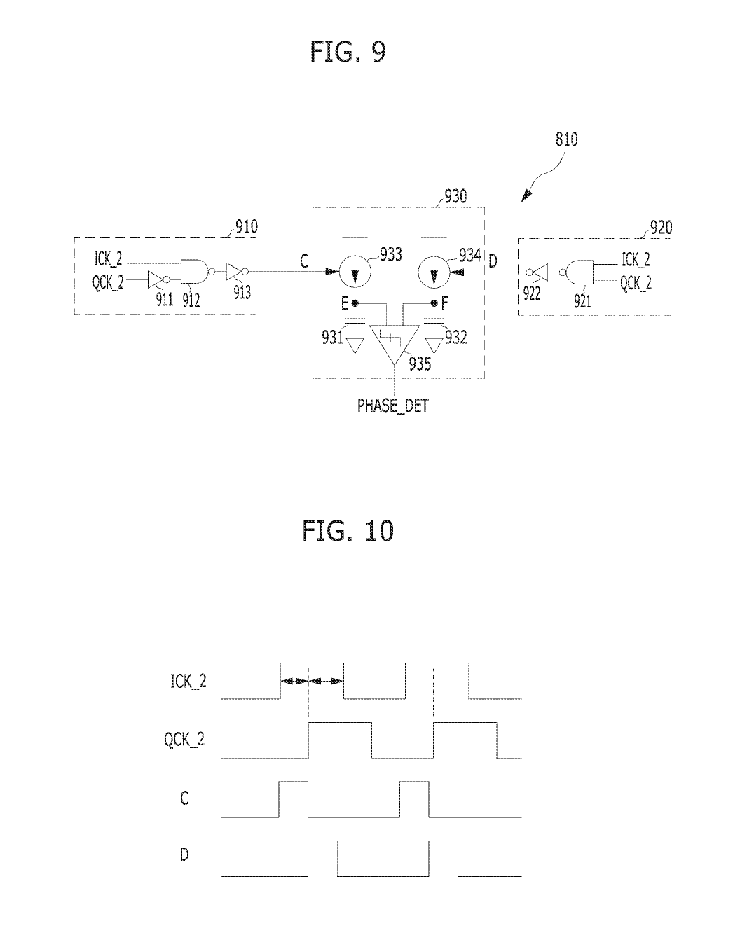

FIG. 9 is a schematic diagram illustrating the phase skew detector 810 shown in FIG. 8.

Referring to FIG. 9, the phase skew detector 810 may include a first pulse generator 910, a second pulse generator 920, and a pulse width comparison circuit 930.

The first pulse generator 910 may generate a pulse signal C which is enabled from a rising edge of the clock ICK_2 to a rising edge of the clock QCK_2. The first pulse generator 910 may include inverters 911 and 913 and a NAND gate 912 as shown in FIG. 9.

The second pulse generator 920 may generate a pulse signal D which is enabled from a rising edge of the clock QCK_2 to a falling edge of the clock ICK_2. The second pulse generator 920 may include a NAND gate 921 and an inverter 922. Referring to FIG. 10, the clocks ICK_2 and QCK_2 and the pulse signals C and D may be easily understood.

The pulse width comparison circuit 930 may generate a phase detection result PHASE_DET by comparing the pulse widths of the pulse signals C and D. When the pulse width of the pulse signal D is wider than the pulse width of the pulse signal C, it may mean that the phase difference between the clocks ICK_2 and QCK_2 is smaller than approximately 90°. Thus, the phase detection result PHASE_DET may be generated in a logic high level. When the pulse width of the pulse signal C is wider than the pulse width of the pulse signal D, it may mean that the phase difference between the clocks ICK_2 and QCK_2 is greater than approximately 90°. Thus, the phase detection result PHASE_DET may be generated in a logic low level. The pulse width comparison circuit 930 may include a capacitor 931 that is coupled between a node E and a ground terminal, a capacitor 932 that is coupled between a node F and the ground terminal, a current source 933 for supplying a current to the node E in response to the pulse signal C, a current source 934 for supplying a current to the node F in response to the pulse signal D, and a comparator 935 for generating the phase detection result PHASE_DET by comparing the voltage levels of the node E and the node F. The voltage level of the node E may have a value which is in proportion to the pulse width of the pulse signal C, and the voltage level of the node F may have a value which is in proportion to the pulse width of the pulse signal D. Therefore, it may be possible to compare the pulse widths of the pulse signals C and D by comparing the voltage levels of the nodes E and F.

According to the embodiments of the present invention, a duty cycle of a clock may be accurately corrected, and a phase difference between multi-phase clocks may be accurately corrected.

While the present invention has been described with respect to the specific embodiments, it will be apparent to those skilled in the art that various changes and modifications may be made without departing from the spirit and scope of the invention as defined in the following claims.

What is claimed is:

1. A duty cycle correction circuit, comprising:
a first inverter suitable for driving a second clock in response to a first clock;
a second inverter suitable for driving the first clock in response to the second clock; and
a duty cycle detector suitable for detecting a duty cycle of the first clock and the second clock,
wherein driving forces of one or more inverters among the first inverter and the second inverter are controlled based on a duty detection result of the duty cycle detector.

2. The duty cycle correction circuit of claim 1, wherein when the duty detection result shows that a high pulse width of the first clock is longer than a high pulse width of the second clock, a driving force of the second inverter is increased, and
when the duty detection result shows that the high pulse width of the second clock is longer than the high pulse width of the first clock, a driving force of the first inverter is increased.

3. The duty cycle correction circuit of claim 1, wherein when the duty detection result shows that a high pulse width of the first clock is longer than a high pulse width of the second clock, a driving force of the first inverter is decreased, and
when the duty detection result shows that the high pulse width of the second clock is longer than the high pulse width of the first clock, a driving force of the second inverter is decreased.

4. The duty cycle correction circuit of claim 1, wherein the duty cycle detector includes:
a first low pass filter suitable for filtering the first clock;
a second low pass filter suitable for filtering the second clock; and
a comparator suitable for generating the duty detection result by comparing a filtered value of the first low pass filter with a filtered value of the second low pass filter.

5. The duty cycle correction circuit of claim 1, further comprising:
a driving force controlling circuit suitable for controlling driving forces of the first inverter and the second inverter in response to the duty detection result of the duty cycle detector.

6. The duty cycle correction circuit of claim 1, further comprising:
a first driver suitable for transferring the first clock to an input terminal of the first inverter;
a second driver suitable for transferring the second clock to an input terminal of the second inverter;
a third driver suitable for transferring the first clock over an output terminal of the second inverter to the duty cycle detector; and
a fourth driver suitable for transferring the second clock over an output terminal of the first inverter to the duty cycle detector.

7. A clock correction circuit, comprising:
a first duty cycle correction circuit suitable for correcting a duty cycle of a first clock and a duty cycle of a second clock;
a second duty cycle correction circuit suitable for correcting a duty cycle of a third clock and a duty cycle of a fourth clock;
a phase skew detector suitable for detecting a phase difference between the first clock and the third clock; and
a delay circuit suitable for delaying the first clock and the second clock by a first delay value and delaying the third clock and the fourth clock by a second delay value,
wherein one or more delay values of the first delay value and the second delay value are controlled based on a detection result of the phase skew detector.

8. The clock correction circuit of claim 7, wherein a target duty cycle ratio of the first to fourth clocks is approximately 50%, and
a target phase difference between the first clock and the third clock is approximately 90°, and
a target phase difference between the third clock and the second clock is approximately 90°, and
a target phase difference between the second clock and the fourth clock is approximately 90°.

9. The clock correction circuit of claim 8, wherein when the detection result of the phase skew detector shows that a phase difference between the first clock and the third clock is greater than approximately 900, the first delay value is controlled to be increased, and
when the detection result of the phase skew detector shows that a phase difference between the first clock and the third clock is smaller than approximately 90°, the second delay value is controlled to be increased.

10. The clock correction circuit of claim 8, wherein when the detection result of the phase skew detector shows that a phase difference between the first clock and the third clock is greater than approximately 90°, the second delay value is controlled to be decreased, and
when the detection result of the phase skew detector shows that a phase difference between the first clock and the third clock is smaller than approximately 90°, the first delay value is controlled to be decreased.

11. The clock correction circuit of claim 7, wherein the phase skew detector includes:
a first pulse generator suitable for generating a first pulse signal which is enabled from a rising edge of the first clock and a rising edge of the third clock;
a second pulse generator suitable for generating a second pulse signal which is enabled from a rising edge of the third clock and a falling edge of the first clock; and
a pulse width comparison circuit suitable for generating the detection result of the phase skew detector by comparing a pulse width of the first pulse signal with a pulse width of the second pulse signal.

12. The clock correction circuit of claim 11, wherein the pulse width comparison circuit includes:
a first capacitor that is coupled between a first node and a ground terminal;
a second capacitor that is coupled between a second node and the ground terminal;
a first current source suitable for supplying a current to the first node in response to the first pulse signal;
a second current source suitable for supplying a current to the second node in response to the second pulse signal; and
a comparator suitable for generating the detection result of the phase skew detector by comparing a voltage level of the first node with a voltage level of the second node.

13. The clock correction circuit of claim 8, further comprising:
a delay value controlling circuit suitable for controlling the first delay value and the second delay value in response to the detection result of the phase skew detector.

14. The clock correction circuit of claim 7, wherein the first duty cycle correction circuit includes:
a first inverter suitable for driving the second clock in response to the first clock;
a second inverter suitable for driving the first clock in response to the second clock; and
a first duty cycle detector suitable for detecting a duty cycle of the first clock and a duty cycle of the second clock, and
driving forces of one or more inverters of the first inverter and the second inverter are controlled based on the detection result of the first duty cycle detector.

15. The clock correction circuit of claim 14, wherein the second duty cycle correction circuit includes:
a third inverter suitable for driving the fourth clock in response to the third clock;
a fourth inverter suitable for driving the third clock in response to the fourth clock; and
a second duty cycle detector suitable for detecting a duty cycle of the third clock and a duty cycle of the fourth clock, and
driving forces of one or more inverters of the third inverter and the fourth inverter are controlled based on the duty detection result of the second duty cycle detector.

16. The clock correction circuit of claim 15, wherein when the duty detection result of the first duty cycle detector shows that a high pulse width of the first clock is longer than a high pulse width of the second clock, a driving force of the second inverter is increased,
when the duty detection result of the first duty cycle detector shows that a high pulse width of the second clock is longer than a high pulse width of the first clock, a driving force of the first inverter is increased,
when the duty detection result of the second duty cycle detector shows that a high pulse width of the third clock is longer than a high pulse width of the fourth clock, a driving force of the fourth inverter is increased, and
when the duty detection result of the second duty cycle detector shows that a high pulse width of the fourth clock is longer than a high pulse width of the third clock, a driving force of the third inverter is increased.

17. The clock correction circuit of claim 16, wherein when the duty detection result of the first duty cycle detector shows that a high pulse width of the first clock is longer than a high pulse width of the second clock, a driving force of the first inverter is decreased,
when the duty detection result of the first duty cycle detector shows that a high pulse width of the second clock is longer than a high pulse width of the first clock, a driving force of the second inverter is decreased,
when the duty detection result of the second duty cycle detector shows that a high pulse width of the third clock is longer than a high pulse width of the fourth clock, a driving force of the third inverter is decreased, and
when the duty detection result of the second duty cycle detector shows that a high pulse width of the fourth clock is longer than a high pulse width of the third clock, a driving force of the fourth inverter is decreased.

18. The clock correction circuit of claim 7, wherein the delay circuit includes:
a first variable delay line suitable for delaying the first clock by the first delay value that is controlled based on the detection result of the phase skew detector;
a second variable delay line suitable for delaying the second clock by the first delay value;
a third variable delay line suitable for delaying the third clock by the second delay value that is controlled based on the detection result of the phase skew detector; and
a fourth variable delay line suitable for delaying the fourth clock by the second delay value.

19. A clock correction circuit for use in a semiconductor memory device, comprising:
a first inverter suitable for driving a second clock in response to a first clock;
a second inverter suitable for driving the first clock in response to the second clock;
a duty cycle detector suitable for detecting a duty cycle of the first clock or the second clock; and
a driving force controlling circuit suitable for controlling driving forces of one or more inverters among the first inverter and the second inverter based on a duty detection result of the duty cycle detector to correct the duty cycle of the first clock and the duty cycle of the second clock.

20. The clock correction circuit of claim 19, further comprising:
a third inverter suitable for driving a fourth clock in response to a third clock;
a fourth inverter suitable for driving the third clock in response to the fourth clock;
a second duty cycle detector suitable for detecting a duty cycle of the third clock or the fourth clock; and
a second driving force controlling circuit suitable for controlling driving forces of one or more inverters among the third inverter and the fourth inverter based on a duty detection result of the duty cycle detector to correct the duty cycle of the third and the duty cycle of the fourth clock.
